(19) United States
(12) Patent Application Publication
(10) Pub. No.: US 2005/0214998 A1
(43) Pub. Date: Sep. 29, 2005

(54) Local stress control for CMOS performance enhancement

(75) Inventors: Chien-Hao Chen, Ilan (TW); Chia-Lin Chen, Hsinchu (TW); Tze-Liang Lee, Hsinchu (TW); Shih-Chang Chen, Hsin-Chu (TW)

Correspondence Address: THOMAS, KAYDEN, HOSTEMEYER & RISLEY LLP, 100 GALLERIA PARKWAY, SUITE 1750, ATLANTA, GA, 30339, US

(73) Assignee: Taiwan Semiconductor Manufacturing Co., Ltd.

(21) Appl. No.: 10/810,795

(22) Filed: Mar. 26, 2004

(51) Int. Cl. H01L 21/44; H01L 21/8238

(52) U.S. Cl. 438/199; 438/233; 438/675; 438/682; 438/683

(57) ABSTRACT

A semiconductor device and method for forming the same for improving charge mobility in NMOS and PMOS devices simultaneously, the method including forming a first dielectric layer including a stress type selected from the group consisting of tensile stress and compressive stress over the respective PMOS and NMOS device regions; removing a portion of the first dielectric layer overlying one of the PMOS and NMOS device regions; forming a second dielectric layer including a stress type opposite from the first dielectric layer stress type over the respective PMOS and NMOS device regions; and, removing a portion of the second dielectric layer overlying one of the PMOS and NMOS device regions having an underlying first dielectric layer to form a compressive stress dielectric layer over the PMOS device region and a tensile stress dielectric layer over the NMOS device region.

### FIELD OF THE INVENTION

This invention generally relates to formation of CMOS devices in integrated circuit manufacturing processes and more particularly to a CMOS device and method that simultaneously achieves mechanically stressed enhanced device performance for both PMOS and NMOS devices.

### BACKGROUND OF THE INVENTION

Mechanical stresses are known to play a role in charge carrier mobility which affects Voltage threshold and drive current (I_{d}). The effect of induced strain in a channel region of a CMOS device by mechanical stresses affects several critical device performance characteristics including drive current (I_{d}) and particularly drive current saturation levels (I_{Dsat}), believed to be related to alteration in charge carrier mobility related to by complex physical processes such as acoustic and optical phonon scattering.

Generally, manufacturing processes are known to introduce stress into the CMOS device channel region. For example, stress is typically introduced into the channel region by formation of an overlying polysilicon gate structure and silicide formation processes. In addition, ion implantation and annealing processes following formation of the gate structure typically introduce additional stresses into the polysilicon gate structure which are translated into the underlying channel region altering device performance.

Prior art processes have also attempted to introduce mechanical stresses into the channel region by forming of a contact etching stop layer over the polysilicon gate structure following a silicide formation process. This approach have met with limited success, however, since the formation the contact etching stop layer, formed with a selected type of stress, e.g., either tensile or compressive degrades device performance of a device of opposite charge carrier polarity (e.g., PMOS, NMOS) which is also covered by the stressed contact etching stop layer.

Some efforts in the prior art that have been proposed to overcome the device degradation of a CMOS of opposite polarity has been ion implanting the contact etching stop layer overlying the opposite polarity device with Ge ions to relax the stress in the contact etch stop layer. For example, a nitride contact etch stop layers of the prior art have been formed with relatively high level of tensile stress requiring a high level of ion implantation to relax the stress of selected polarity devices. As a result, the nitride contact etching stop layer is severely damaged, which can have the effect of undesirably changing etching rates and causing unintentional overetching in subsequent processes, for example causing damage to underlying silicon or polysilicon portions of a CMOS device, degrading device performance and reliability.

These and other shortcomings demonstrate a need in the semiconductor device integrated circuit manufacturing art for improved CMOS devices and manufacturing methods to selectively control a local mechanical stress level in a CMOS device to improve device performance and reliability without degrading device performance of devices of opposite polarity while increasing device performance and reliability without regard to device polarity.

It is therefore an object of the present invention to provide a CMOS device and manufacturing method to selectively control a local mechanical stress level in a CMOS device to simultaneously improve both NMOS and PMOS device performance and reliability, in addition to overcoming other shortcomings of the prior art.

### SUMMARY OF THE INVENTION

To achieve the foregoing and other objects, and in accordance with the purposes of the present invention, as embodied and broadly described herein, the present invention provides a semiconductor device and method for forming the same for improving charge mobility in NMOS and PMOS devices simultaneously.

In a first embodiment, the method includes forming a first dielectric layer including a stress type selected from the group consisting of tensile stress and compressive stress over the respective PMOS and NMOS device regions; removing a portion of the first dielectric layer overlying one of the PMOS and NMOS device regions; forming a second dielectric layer including a stress type opposite from the first dielectric layer stress type over the respective PMOS and NMOS device regions; and, removing a portion of the second dielectric layer overlying one of the PMOS and NMOS device regions having an underlying first dielectric layer to form a compressive stress dielectric layer over the PMOS device region and a tensile stress dielectric layer over the NMOS device region.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1F are cross sectional schematic representations of exemplary portions of a semiconductor device comprising an NMOS and PMOS device pair at stages of manufacture according to an embodiment of the present invention.

FIG. 2 is an exemplary process flow diagram including several embodiments of the present invention.

### DETAILED DESCRIPTION OF THE PREFERRED EMBODIMENTS

Although the method of the present invention is explained with reference to an exemplary NMOS and PMOS device pair, it will be appreciated that the method of the present invention may be applied to the formation of any CMOS device where a local tensile and compressive stress is controllably introduced into a respective NMOS and PMOS device region including a channel region to achieve simultaneous device performance improvement including an increase in drive current (Id).

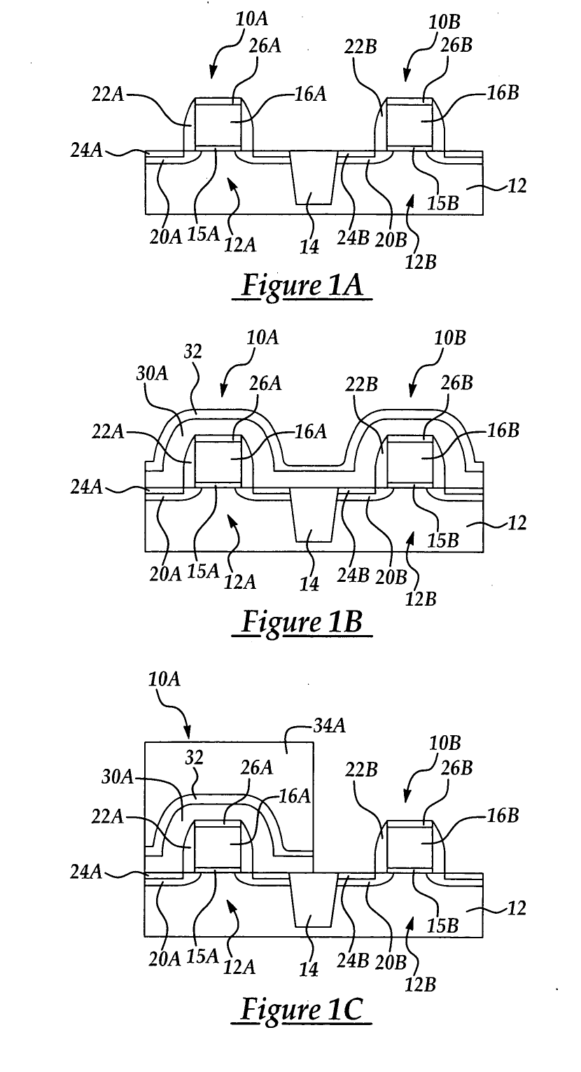

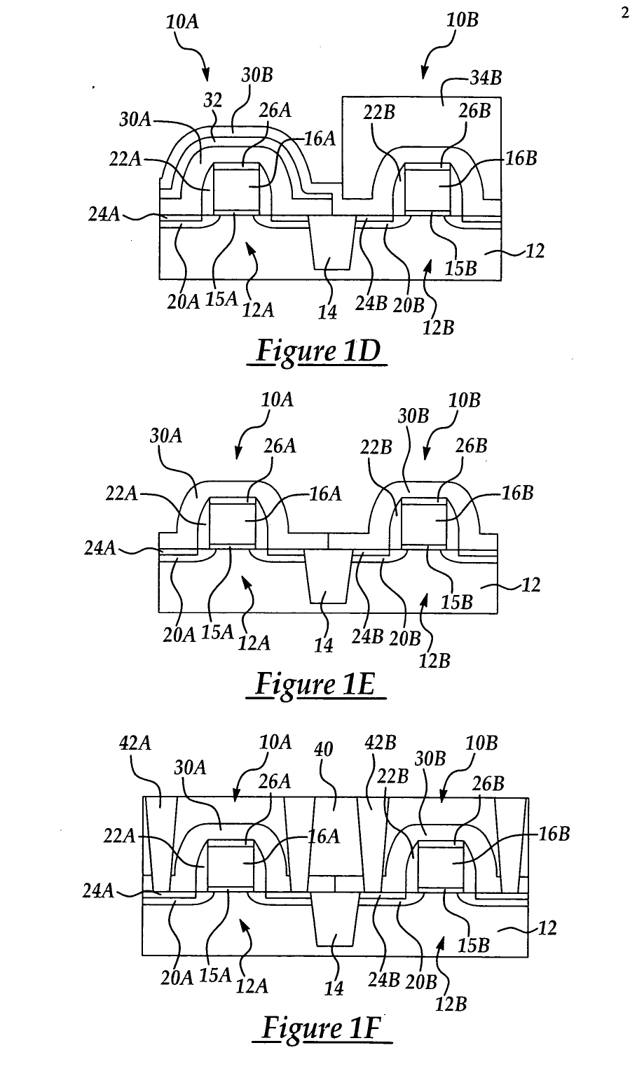

Referring to FIGS. 1A-1F in an exemplary embodiment of the method of the present invention, are shown cross-sectional schematic views of a portion of a semiconductor wafer during stages in production of CMOS structures including an NMOS and PMOS device pair e.g., 10A and 10B respectively. For example, referring to FIG. 1A is shown a silicon substrate 12 including respective NMOS regions 12A and PMOS region 12B separated by an isolation region, preferably a shallow trench isolation (STI) structure, e.g., 14 which is formed by conventional methods including backfilling an STI trench with an oxide dielectric, for example TEOS oxide.

Still referring to FIG. 1A, gate structures including a gate dielectric portions e.g., 15A and 15B and gate electrode portions 16A and 16B. Preferably the gate dielectric e.g., 15A may be formed by any process known in the art, e.g., thermal oxidation, nitridation, sputter deposition, or chemical vapor deposition. The physical thickness of the gate dielectric e.g., 15A is preferably in the range of 5 to 100 Angstroms. When using a high permittivity (high-K) dielectric, preferably the dielectric constant is greater than about 8. The high-K dielectric is preferably selected from a group comprising aluminum oxide (Al₂O₃), hafnium oxide (HfO₂), hafnium oxynitride (HfON), hafnium silicate (HfSiO₄), zirconium oxide (ZrO₂), zirconium oxynitride (ZrON), zirconium silicate (ZrSiO₂), yttrium oxide (Y₂O₃), lanthanum oxide (La₂O₃), cerium oxide (CeO₂), titanium oxide (TiO₂), tantalum oxide (Ta₂O₅), or combinations thereof. The silicon oxide equivalent oxide thickness (EOT) of the gate dielectric is preferably larger than about 5 Angstroms, more preferably larger than about 20 Angstroms, and even more preferably larger than about 40 Angstroms.

The gate electrode e.g., 16A may be formed of polysilicon, polysilicon-germanium, metals, metal silicides, metal nitrides, or conductive metal oxides. In a preferred embodiment, the gate electrode is formed of polysilicon. Metals such as molybdenum, tungsten, titanium, tantalum, platinum, and hafnium may be used in an upper portion of the gate electrodes e.g., 16A, 16B. Metal nitrides may include, but are not limited to, molybdenum nitride, tungsten nitride, titanium nitride, and tantalum nitride. Conductive metal oxides may include, but are not limited to, ruthenium oxide and indium tin oxide.

The gate electrode material may be deposited by conventional techniques such as CVD methods. The gate electrode material may also be formed by the deposition of silicon and metal, followed by an annealing process to form a metal silicide gate electrode material. A patterned gate mask is then formed on the gate electrode material using deposition and photolithographic techniques. The gate mask may employ commonly used masking materials such as, but not limited to, silicon oxide silicon oxynitride, and silicon nitride. The gate material is then etched according to the gate mask using a plasma etch process to form the gate electrode, e.g., 16A, 16B. Conventional source/drain extension (SDE) regions forming a portion of subsequent formed S/D region e.g., 20A, 20B are by a conventional ion implant process adjacent the polysilicon electrodes to a shallow depth e.g., (30 to 100 nm) prior to offset spacer formation.

Still referring to FIG. 1A, sidewall spacers e.g., 22A and 22B, also referred to as dielectric offset spacers, are formed along the gate electrode sidewalls by depositing one or more offset dielectric layers of oxide and nitride to form, for example, oxide, oxide/nitride, or oxide/nitride/oxide layers followed by etching away portions of the offset dielectric layers to form offset spacers (sidewall spacers) e.g., 22A and 22B, on either side of the gate electrodes e.g., 16A, 16B.

Following sidewall spacer formation, the NMOS and PMOS device areas are sequentially doped according to a conventional a high dose ion implantation (HDI) process to form source/drain (S/D) regions e.g., 20A and 20B in the silicon substrate adjacent the offset spacers. The gate electrodes 16A and 16B are preferably doped at the same time the HDI is carried out to lower a sheet resistance of the gate electrode material.

Still referring to FIG. 1A, self aligned silicides (salicides) e.g., 24A, 24B, are then formed by conventional processes over the S/D regions 20A, 20B and over the upper portion e.g., 26A, 26B of the gate electrodes e.g., 16A, 16B. For example, TiSi₂ or CoSi₂ silicides are formed by conventional processes including titanium or cobalt deposition over exposed silicon S/D portions e.g., 20A, 20B and upper gate electrode portions e.g., 16A, 16B followed by annealing processes to form the low electrical resistance silicide phase as is known in the art.

Referring to FIG. 1B, according to an important aspect of the invention, at least one first dielectric layer e.g., 30A is blanket deposited in one of compressive and tensile stress to cover the NMOS and PMOS regions formed. The at least one first dielectric layer 30A may be any dielectric layer that can be deposited in tensile and or compressive stress, but preferably is formed of at least one of silicon nitride (e.g., SiN, SiₓN_{y}), and silicon oxynitride (e.g., SiₓON_{y}), most preferably silicon nitride, where the stoichiometric proportions x and y may be varied according to CVD process variables as are known in the art to achieve a desired tensile or compressive stress in a deposited dielectric layer. Most preferably the first dielectric layer 30A is formed of silicon nitride by a conventional CVD process using conventional silane and/or chlorosilane source gases including silane (SiH₄), disilane (Si₂H₆), trisilane (Si₃H₈), dichlorosilane (SiH₂Cl₂), trichlorosilane (SiHCl₃), hexacholorodisilane (Si₂Cl₆), and the like, or mixtures thereof. Other silicon nitride forming precursors as are known in the art may be used as well. For example, the CVD process may be a low pressure chemical vapor deposition (LPCVD) process, an atomic layer CVD (ALCVD) process, or a plasma enhanced CVD (PECVD) process.

In the exemplary embodiment as shown, the first dielectric layer 30A is deposited in tensile stress over both the NMOS device and PMOS device regions e.g., 12A and 12B. Preferably, the first dielectric layer 30A is deposited to be in tensile stress, having a tensile stress up to about 2 GPa. It will be appreciated that the level of the tensile stress can be varied by a number of factors including the thickness of the dielectric film, preferably being from about 10 Angstroms to about 1000 Angstroms in thickness.

Following formation of the first dielectric layer 30A, a buffer oxide layer e.g., 32, for example CVD oxide, e.g., TEOS oxide, having a thickness of from about 10 Angstroms to about 1000 Angstroms is optionally formed by a conventional CVD process over the first dielectric layer 30A to act as a buffer layer in a subsequent dry etching process to act as an etching endpoint detection layer to prevent over etching of the first dielectric layer 30A and affecting a deposited stress level in a subsequent dry etching process as outlined below.

Referring to FIG. 1C, following formation of the first dielectric layer 30A and the buffer oxide layer 32, a resist patterning process is carried out to form resist portion 34A covering the NMOS regions 12A, including about half of the STI structure 14. The NMOS and PMOS device regions are then subjected to a conventional wet and/or dry etching process to remove the oxide buffer layer 32 and first dielectric layer 30A over the uncovered PMOS region 12B.

Referring to FIG. 1D, following removal of the buffer oxide layer 32, the first dielectric layer 30A, and the resist portion 34A over the NMOS region 12A, a second dielectric layer 30B is formed over the NMOS device regions 12A and the PMOS device region 12B according to the same preferred embodiments for forming the first dielectric layer 30A excepting that the second dielectric layer 30B is now formed in compressive stress, preferably having a stress level of up to about 2 GPa and a thickness up to about 1000 Angstroms, for example for about 10 Angstroms to about 1000 Angstroms depending on the desired stress level to be imparted to the PMOS device 10B including a channel region.

It will be appreciated that the order of the processing steps e.g., depositing the first dielectric layer 30A in tensile stress followed by removal of the tensile stress dielectric layer 30A over the PMOS device region 12B and deposition of a compressive stress dielectric layer 30B over both the NMOS and PMOS device regions may be reversed with respect to the NMOS and PMOS device regions. For example, the method of the present invention may also be carried out by depositing the first dielectric layer e.g., 30A in compressive stress followed by removal of the compressive stress dielectric layer over the NMOS device regions and deposition of a tensile stress layer e.g., 30B over the NMOS and PMOS device regions.

Still referring to FIG. 1D, a conventional photolithographic patterning process is then carried out form a resist layer portion 34B covering the PMOS device region 12B to etch away portions of the dielectric layer 30B over the NMOS device region 12A including over about half of width of the STI structure 14. It will be appreciated that the respective compressive stress layers and tensile stress dielectric layers may be formed to have different thicknesses as well as forming overlapping layer portions or a gap at the interface of the respective layer, where the interface is formed over an electrical isolation region, e.g., STI structure 14.

Referring to FIG. 1E, a conventional wet and/dry etching process is then carried out to remove the second dielectric layer 30B and optionally, but preferably, the oxide buffer layer 32 over the NMOS device region 12A thereby leaving first dielectric layer 30A in tensile stress overlying the NMOS device region 12A and second dielectric layer 30B in compressive stress overlying the PMOS device region 12B.

As explained previously, advantageously, the presence of the tensile stress dielectric layer (e.g., 30A) acts to impart a relatively tensile stress to the channel region e.g., e.g., underlying gate dielectric portions e.g., 15A and 15B, thereby enhancing electron mobility in the channel regions. In an important aspect of the invention, the compressive stress dielectric layer (e.g., 30B) formed over the PMOS device region 12B simultaneously acts to impart a relatively compressive stress to the PMOS device channel region thereby enhancing hole mobility. As such, the charge carrier mobility is advantageously simultaneously enhanced in both NMOS and PMOS device channel regions according to an embodiment of the present invention.

Referring to FIG. 1F, Following formation of the tensile and compressive stress layers over respective NMOS and PMOS devices, conventional subsequent processes are carried out to form integrated circuit wiring, for example depositing an overlying inter-layer dielectric (ILD) layer e.g., 40, a planarization step followed by conventional photolithographic patterning and etching process to form metal damascene contacts e.g., 42A and 42B, for example backfilled tungsten to form electric contact wiring with the salicide regions e.g., 26A and 26B.

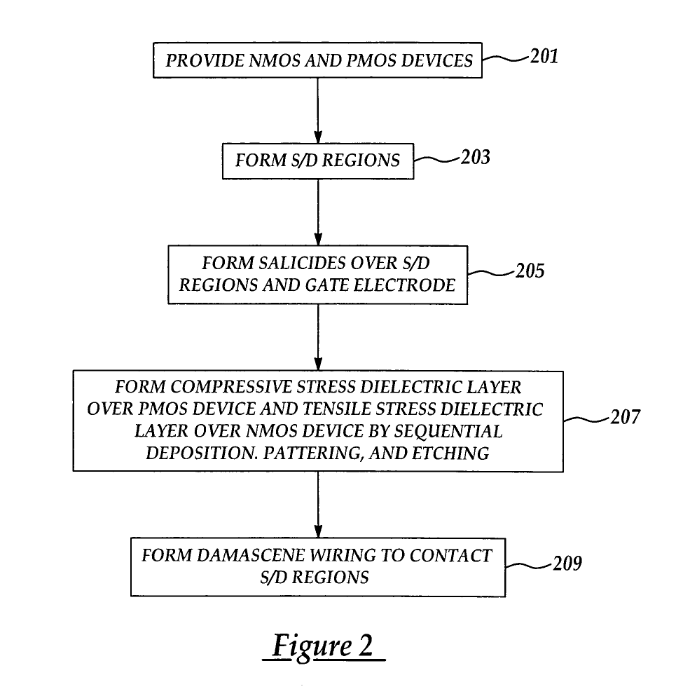

Referring to FIG. 2 is a process flow diagram including several embodiments of the present invention. In process 201, a semiconductor substrate including NMOS and PMOS devices comprising respective gate structures, SDE regions and offset spacers is provided. In process 203, a HDI implant process is carried out to form respective S/D regions. In process 205 salicides are formed over the respective S/D regions and over upper portions of respective gate electrodes. In process 207, sequential deposition, patterning and etching processes are carried out form a first dielectric layer in tensile stress over the NMOS device region and a second dielectric layer in compressive stress over the PMOS device region according to preferred embodiments. In process 209, conventional processes are carried out including an etching process to form damascene wiring interconnects over at least the S/D regions of the NMOS and PMOS device pair.

Thus a method has been presented for selectively delivering a selected stress level and type to both NMOS and PMOS device channel regions to simultaneously improve charge carrier mobility and device performance including current drive (I_{D}). Among the several advantages of the present invention over the prior art include the fact that an ion implantation to relax a stress type over a selected polarity device is not required, thereby avoiding ion implant induced damage to the stressed dielectric layer, for example a contact etching stop layer. As a result, the etching properties of the stressed dielectric layer (contact etching stop layer) are not altered, thereby improving subsequent etching processes, for example forming contact openings for forming metal contacts to the CMOS device, and thereby avoiding damage to underlying CMOS silicide and silicon portions to improve both device performance and reliability.

The preferred embodiments, aspects, and features of the invention having been described, it will be apparent to those skilled in the art that numerous variations, modifications, and substitutions may be made without departing from the spirit of the invention as disclosed and further claimed below.

1. A method for improving charge mobility of both NMOS and PMOS devices comprising the steps of:
providing a semiconductor substrate comprising gate structures overlying respective PMOS and NMOS device regions;
forming suicides adjacent the respective gate structures and over an upper portion of the respective gate structures;
forming a first dielectric layer comprising a stress type selected from the group consisting of tensile stress and compressive stress over the respective PMOS and NMOS device regions;
removing a portion of the first dielectric layer overlying one of the PMOS and NMOS device regions;
forming a second dielectric layer comprising a stress type opposite from the first dielectric layer stress type over the respective PMOS and NMOS device regions; and
removing a portion of the second dielectric layer overlying one of the PMOS and NMOS device regions having the underlying first dielectric layer to form a compressive stress dielectric layer over the PMOS device region and a tensile stress dielectric layer over the NMOS device region.

2. The method of claim 1, further comprising forming a buffer oxide layer over the compressive stress dielectric layer and tensile stress dielectric layer.

3. The method of claim 2, wherein the buffer oxide layer comprises a silicon oxide layer.

4. The method of claim 2, wherein the buffer oxide layer is from about 10 Angstroms to about 1000 Angstroms in thickness.

5. The method of claim 1, wherein the first and second dielectric layers comprises a material selected from the group consisting of silicon nitride and silicon oxynitride.

6. The method of claim 1, wherein the first and second dielectric layers are formed by a CVD deposition process selected from the group consisting of LPCVD, ALCVD, and PECVD.

7. The method of claim 6, wherein the first and second dielectric layers are formed by precursors comprising reactants selected from the group consisting of silane (SiH₄), disilane (Si₂H₆), trisilane (Si₃H₈), dichlorosilane (SiH₂Cl₂), trichlorosilane (SiHCl₃), hexacholorodisilane (Si₂Cl₆), and mixtures thereof.

8. The method of claim 1, wherein the first and second dielectric layers are from about 10 Angstroms to about 1000 Angstroms in thickness.

9. The method of claim 1, wherein the compressive stress dielectric layer and the tensile stress dielectric layer comprise a stress level up to about 2 GPa.

10. The method of claim 1, wherein the silicide comprises a metal silicide.

11. The method of claim 10 wherein the metal silicide is selected from the group consisting of cobalt silicide and titanium silicide.

12. The method of claim 1, wherein the first and second dielectric layers are formed without a subsequent ion implantation process to relieve a stress level.

13. The method of claim 1, wherein the first and second dielectric layers form a contact etching stop layer in a subsequent damascene formation process.

14. A method for simultaneously improving charge mobility and device drive current of NMOS and PMOS devices comprising the steps of:
providing a semiconductor substrate comprising gate structures and offset spacers overlying respective PMOS and NMOS device regions;
forming source/drain regions;
forming silicides over the source/drain regions and over an upper portion of the respective gate structures;
forming a first dielectric layer comprising a stress type selected from the group consisting of tensile stress and compressive stress over the respective PMOS and NMOS device regions;
removing a portion of the first dielectric layer overlying one of the PMOS and NMOS device regions;
forming a second dielectric layer comprising a stress type opposite from the first dielectric layer stress type over the respective PMOS and NMOS device regions; and
removing the second dielectric layer overlying one of the PMOS and NMOS device regions to form a compressive stress dielectric layer over the PMOS device region and a tensile stress dielectric layer over the NMOS device region.

15. The method of claim 14, further comprising forming a buffer oxide layer over the compressive stress dielectric layer and tensile stress dielectric layer.

16. The method of claim 15, wherein the buffer oxide layer comprises a silicon oxide layer.

17. The method of claim 15, wherein the buffer oxide layer is from about 10 Angstroms to about 1000 Angstroms in thickness.

18. The method of claim 14, wherein the first and second dielectric layers comprise a material selected from the group consisting of silicon nitride and silicon oxynitride.

19. The method of claim 14, wherein the first and second dielectric layers are formed by a CVD deposition process selected from the group consisting of LPCVD, ALCVD, and PECVD.

20. The method of claim 19, wherein the first and second dielectric layers are formed by precursors comprising a reactant selected from the group consisting of silane (SiH₄), disilane (Si₂H₆), trisilane (Si₃H₈), dichlorosilane (SiH₂Cl₂), trichlorosilane (SiHCl₃), hexacholorodisilane (Si₂Cl₆), and mixtures thereof.

21. The method of claim 14, wherein the first an second dielectric layers are from about 10 Angstroms to about 1000 Angstroms in thickness.

22. The method of claim 14, wherein the compressive stress dielectric layer and the tensile stress dielectric layer comprise a stress level up to about 2 GPa.

23. The method of claim 14, wherein the silicides comprise a metal silicide selected from the group consisting of cobalt silicide and titanium silicide.

24. The method of claim 14, wherein the first and second dielectric layers are formed without a subsequent ion implantation process to relieve a stress level.

25. The method of claim 1, wherein the first and second dielectric layers form a contact etching stop layer in a subsequent damascene formation process.

26-39. (canceled)

40. A method for manufacturing a semiconductor device, comprising:
providing a semiconductor substrate comprising a first gate structure overlying a PMOS device region and a second gate structure overlying a NMOS device region;
forming a first layer with first stress over the NMOS region; and
forming a second layer with second stress over the PMOS region such that an interface is formed between the first layer and the second layer;
wherein the second stress is different from the first stress.
